(19) United States
(12) Patent Application Publication
(10) Pub. No.: US 2002/0004254 A1
(43) Pub. Date: Jan. 10, 2002

(54) Method for producing p-type gallium nitride-based compound semiconductor, method for producing gallium nitride-based compound semiconductor light-emitting device, and gallium nitride-based compound semiconductor light-emitting device

(75) Inventors: Hisayuki Miki, Saitama (JP); Mineo Okuyama, Saitama (JP); Masaharu Oshima, Tokyo (JP); Hiroshi Fujioka, Tokyo (JP); Ichitaro Waki, Tokyo (JP)

Correspondence Address: SUGHRUE, MION, ZINN, MACPEAK & SEAS, PLLC, 2100 Pennsylvania Avenue, N.W., Washington, DC, 20037-3213, US

(73) Assignee: SHOWA DENKO KABUSHIKI KAISHA

(21) Appl. No.: 09/900,962

(22) Filed: Jul. 10, 2001

Related U.S. Application Data
(60) Provisional application No. 60/247,991, filed on Nov. 14, 2000.

(30) Foreign Application Priority Data
Jul. 10, 2000 (JP) P2000-207701

(51) Int. Cl. H01L 21/00

(52) U.S. Cl. 438/46; 438/47

(57) ABSTRACT

An object of the present invention is to realize exertion of p-type conduction without incurring deterioration of crystal in the light-emitting layer or generating contamination, production at a low cost and good ohmic contact with an electrode. The method for producing a p-type gallium nitride-based compound semiconductor of the present invention includes producing a gallium nitride-based compound semiconductor layer doped with a p-type impurity, producing a catalyst layer having a metal, alloy or compound on the gallium nitride-based compound semiconductor layer, and annealing the gallium nitride-based compound semiconductor layer fixed with the catalyst layer.

### CROSS REFERENCE TO RELATED APPLICATIONS

This application is an application filed under 35 U.S.C. §111(a) claiming benefit pursuant to 35 U.S.C. §119(e)(1) of the filing date of Provisional Application No. 60/247,991 filed Nov. 14, 2000 pursuant to 35 U.S.C. §111(b).

### FIELD OF THE INVENTION

The present invention relates to a method for producing a p-type gallium nitride-based compound semiconductor, a method for producing a gallium nitride-based compound semiconductor light-emitting device, and a gallium nitride-based compound semiconductor light-emitting device.

### BACKGROUND OF THE INVENTION

In the field of gallium nitride-based compound semiconductor, it has been difficult to form a semiconductor showing p-type conduction. The reasons therefor are considered as follows.

A metal organic chemical vapor deposition (MOCVD) method is generally used for growing a gallium nitride-based compound semiconductor having good crystallinity. However, in the growing apparatus for performing crystal growth by the MOCVD method, a hydrogen gas used as a carrier gas for transporting a starting material compound onto a substrate, a hydrogen molecule generated upon decomposition of ammonia (NH₃) used as a Group-V starting material such as nitrogen, or a radical or atomic hydrogen is present in a high concentration. Such hydrogen is taken inside the crystal during the growth of the crystal layer of gallium nitride-based compound semiconductor and bonds to the doped p-type impurity during cooling from the growing temperature. The p-type impurity passivated by hydrogen is not activated and generates no hole, and therefore, a semiconductor showing p-type conduction can be hardly formed.

On the other hand, it has been found that the p-type impurity passivated by hydrogen in a semiconductor can be dehydrogenated and activated by a method of irradiating a low energy electron beam on Mg-doped gallium nitride (see, JP-A-2-257679) (the term “JP-A” as used herein means an “unexamined published Japanese patent application”) or a method of annealing the same Mg-doped gallium nitride in an atmosphere containing no hydrogen (see, JP-A-5-183189), thereby obtaining a semiconductor showing p-type conduction.

However, the method of using electron-beam irradiation has a problem in that the whole surface of a wafer cannot be uniformly treated or, even if treated, the treatment takes a long period of time or large and expensive equipment is necessary. Therefore, the annealing method capable of homogeneously treating a sample having a wide area is considered industrially suitable for forming a p-type gallium nitride compound semiconductor. However, according to the annealing method disclosed in JP-A-5-183189, the annealing must be performed at a high temperature on the order of 700 to 900° C. for ensuring a high carrier concentration. If the annealing is performed at such a high temperature, the crystal constituting the light-emitting layer is readily damaged. For example, InₓGa₁₋ₓN (0<x≦1), which is a ternary mixed-crystal gallium nitride-based compound semiconductor containing In, causes a spinodal decomposition and the crystal is readily damaged. As a result, a visible light-emitting device having sufficiently high light emission intensity cannot be obtained.

JP-A-11-186605 discloses a technique where, in the method of forming an electrode for a p-type gallium nitride-based compound semiconductor, Pt is formed on a layer doped with an acceptor impurity and thereafter, annealed at a temperature of 400° C. or more in an atmosphere containing at least oxygen, thereby forming an electrode having good flatness. JP-A-11-186605 discloses that not only an electrode having good flatness is formed, but also the acceptor impurity (p-type impurity) contained inside the crystal is activated.

JP-A-11-145518 discloses a method of producing a p-type gallium nitride-based compound semiconductor where Co is deposited on the surface of a gallium nitride-based compound semiconductor doped with an acceptor impurity and then annealed in an oxygen atmosphere and after the annealing, the oxidized Co-film is removed, the annealing temperature can be lowered, the damages on the thin film structure inside the crystal can be reduced, and good surface morphology can be kept.

The methods of JP-A-11-186605 and JP-A-11-145518 above describing a technique of forming a metal thin film on the surface and using a mixed gas containing oxygen for the vapor phase atmosphere gas during annealing to lower the annealing temperature have a problem in that although the annealing temperature is surely lowered, contamination containing oxygen remains on the surface of gallium nitride-based compound semiconductor and cannot be easily removed. This contamination is generally an insulating metal oxide in many cases and inhibits the electrical contact of gallium nitride-based compound semiconductor with an electrode metal. Therefore, the electrode formed on the surface is increased in the contact resistance. Moreover, these contaminants form a solid solution with a solid constituting the crystal due to the temperature during annealing and, in many cases, enter and exist in the inside rather than on the outermost surface, and therefore, complete removal thereof is difficult.

To cope with this, a technique of performing the annealing in an atmosphere gas containing no oxygen at a low temperature to obtain p-type conduction is disclosed in JP-A-11-177134 and JP-A-11-354458. According to this technique, a thin film of Pd as a hydrogen-occluded metal is formed on the surface of a gallium nitride-based compound semiconductor, which is formed by adding an acceptor impurity, and then annealed in an inert gas such as nitrogen gas, whereby the p-type impurity passivated by hydrogen in a semiconductor is dehydrogenated and activated and a semiconductor showing p-type conduction can be obtained. By this technique, the deterioration of crystal and the generation of contamination containing oxygen can be surely prevented.

However, the methods of JP-A-11-177134 and JP-A-11-354458 have a problem in that Pd is formed on the surface and since the Pd is a noble metal, the semiconductor has a high cost. Furthermore, in the case of removing Pd from the surface and newly forming an electrode, Pd is difficult to remove. Therefore, a treatment with a strong acid at a high temperature or a treatment by irradiating a high-energy ray becomes necessary and this disadvantageously damages the surface of the device structure and makes it difficult to form an electrode by ohmic contact.

### SUMMARY OF THE INVENTION

The present invention has been made under these circumstances and objects of the present invention are to provide a method for producing a p-type gallium nitride-based compound semiconductor, where exertion of p-type conduction, low-cost production and good ohmic contact with an electrode can be realized without incurring deterioration of the crystal in the light-emitting layer or causing contamination or generation of damages on the device surface, to provide a method for producing a gallium nitride-based compound semiconductor light-emitting device, and to provide a gallium nitride-based compound semiconductor light-emitting device.

For attaining these objects, the present invention provides the following embodiments.

(1) a method for producing a p-type gallium nitride-based compound semiconductor, comprising a first step of producing a gallium nitride-based compound semiconductor layer doped with a p-type impurity, a second step of producing a catalyst layer comprising a metal, alloy or compound on the gallium nitride-based compound semiconductor layer, and a third step of annealing the gallium nitride-based compound semiconductor layer in the state of being fixed with the catalyst layer.

(2) a method where, in addition to the constitution of the invention described in (1), the catalyst layer comprises a metal, alloy or compound having a smaller heat of formation for a metal hydride compound than that of the p-type impurity.

(3) a method where, in addition to the constitution of the invention described in (2), the catalyst layer is a monolayer or multilayer film comprising a metal, alloy or compound containing at least one element selected from the group consisting of Ni, Co, Fe, Mn, Cr, V, Ti, Re, W, Ta, Hf, Lu, Gd, Ce, La, Ru, Mo, Zr, Y, Au, Ag, Cu, Al and Bi.

(4) a method where, in addition to the constitution of the invention described in (2), the catalyst layer is a monolayer or multilayer film comprising a metal, alloy or compound containing Ni.

(5) a method where, in addition to the constitution of the invention described in any one of (1) to (4), the annealing in the third step is performed at a temperature of 200° C. or more.

(6) a method where, in addition to the constitution of the invention described in any one of (1) to (4), a fourth step of stripping the catalyst layer is provided after the third step.

(7) a method where, in addition to the constitution of the invention described in any one of (1) to (4), the catalyst layer has a film thickness of 1 to 100 nm.

(8) a method for producing a gallium nitride-based compound semiconductor light-emitting device having an n-type layer, a light-emitting layer and a p-type layer each comprising a gallium nitride-based compound semiconductor, the method comprising producing the p-type layer through a first step of producing a gallium nitride-based compound semiconductor layer doped with a p-type impurity, a second step of producing a catalyst layer comprising a metal, alloy or compound or the like on the gallium nitride-based compound semiconductor layer, a third step of annealing the gallium nitride-based compound semiconductor layer in the state of being fixed with the catalyst layer, and a fourth step of stripping the catalyst layer.

(9) a method where, in addition to the constituent of the invention described in (8), the catalyst layer comprises a metal, alloy or compouond having a smaller heat of formation for a metal hydride compound than that of the p-type impurity.

(10) a method where, in addition to the constituent of the invention in (9), the catalyst layer is a monolayer or multilayer film comprising a metal, alloy or compound containing at least one element selected from the group consisting of Ni, Co, Fe, Mn, Cr, V, Ti, Re, W, Ta, Hf, Lu, Gd, Ce, La, Ru, Mo, Zr, Y, Au, Ag, Cu, Al and Bi.

(11) a method where, in addition to the constituent of the invention described in (9), the catalyst layer is a monolayer or multilayer film comprising a metal, alloy or compound containing Ni.

(12) a method where, in addition to the constituent of the invention described in any one of (8) to (11), the annealing in the third step is performed at a temperature of 200° C. or more.

(13) a method where, in addition to the constituent of the invention described in any one of (8) to (11), the catalyst layer has a film thickness of 1 to 100 nm.

(14) a gallium nitride-based compound semiconductor light-emitting device having an n-type layer, a light-emitting layer and a p-type layer each comprising a gallium nitride-based compound semiconductor, wherein the p-type layer is formed by producing a catalyst layer comprising a metal, alloy or compound on a gallium nitride-based compound semiconductor layer doped with a p-type impurity, annealing the gallium nitride-based compound semiconductor layer in the state of being fixed with the catalyst layer, and stripping the catalyst layer, and the p-type impurity in the p-type layer is activated.

### BRIEF DESCRIPTION OF THE DRAWINGS

FIGS. 1(A)-(C) are views of a gallium nitride-based compound semiconductor for explaining the procedure in the method for producing a gallium nitride-based compound semiconductor of the present invention.

FIG. 2 is a plan view schematically showing the annealing furnace for use in the annealing of a sample.

FIG. 3 is a graph showing the relationship between the annealing temperature and the carrier concentration.

FIGS. 4(A)-(C) are views of a semiconductor light-emitting device for explaining the method for producing a semiconductor light-emitting device structure using the p-type gallium nitride-based compound semiconductor produced according to the method of the present invention.

### DESCRIPTION OF THE PRESENT INVENTION

The present invention will be described in further detail with reference to the Figures and Examples, which should not be construed as limiting the scope of the present invention. Unless indicated otherwise, all parts, percents, ratios and the like are by weight.

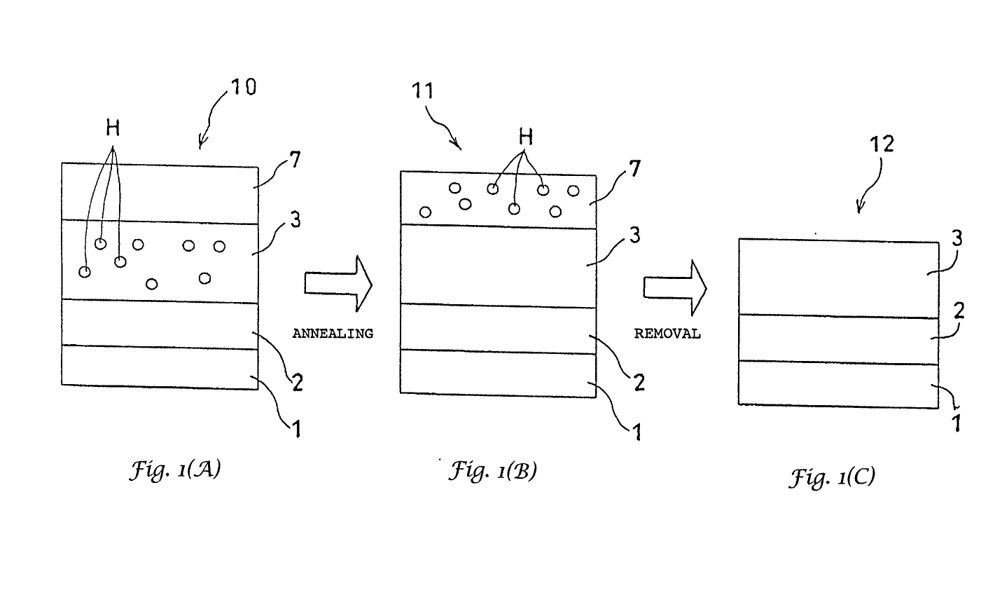

A first embodiment of the present invention is described by referring to FIGS. 1(A)-(C) and Example 1.

### EXAMPLE 1

FIGS. 1(A)-(C) are views for explaining the procedure in the method for producing a p-type gallium nitride-based compound semiconductor of the present invention. The method for producing a p-type gallium nitride-based compound semiconductor of the present invention is described using this figure. As shown in FIG. 1(A), a buffer layer 2 comprising GaN, a p-type layer 3 comprising a GaN doped with Mg and a catalyst layer 7 comprising Ni are formed on a substrate 1 comprising sapphire to construct a multilayer structure (sample) 10. Sample 10 thus obtained is annealed at 300° C. for 10 minutes. As a result of annealing, hydrogen bonded to Mg in the p-type layer 3 migrates and as shown in FIG. 1(B), bonds to Ni in the catalyst layer 7. The resulting Sample 11 is impregnated with hydrochloric acid to remove the catalyst layer 7, thereby forming Sample 12 shown in FIG. 1(C). In the p-type layer 3 of Sample 12, Mg passivated by bonding to hydrogen during the step of forming Sample 10 is activated to increase the carrier concentration, so that the p-type layer 3 can fully exert the p-type function.

This production method is described in greater detail below. First of all, a substrate 1 was introduced into a quartz-made reaction furnace provided within an RF coil of an induction heating-type heater. The substrate 1 was placed on a carbon-made susceptor for heating. After the introduction of sample, the reaction furnace was vacuumized to discharge the air and a nitrogen gas was flowed therethrough to purge the inside of the reactor.

After the nitrogen gas was flowed over 10 minutes, the induction heating-type heater was actuated to elevate the substrate temperature to 1,170° C. over 10 minutes. The substrate was kept at a temperature of 1,170° C. and in this state, left standing for 9 minutes while flowing a hydrogen gas and a nitrogen gas to perform a thermal cleaning of the substrate surface.

During the thermal cleaning, a hydrogen carrier gas was flowed through pipes of containers (bubblers) containing trimethyl gallium (TMG) or cyclopentadienyl magnesium (Cp₂Mg) as starting materials to initiate bubbling. Here, the pipes were connected to a reaction furnace. Each bubbler was adjusted to a constant temperature using a thermobath for the temperature adjustment. Each starting material gases generated by the bubbling each was flowed together with the carrier gas into a pipe connected to a deharmarizing system and discharged outside the system through the deharmarizing system.

After the completion of thermal cleaning, the induction heating-type heater was controlled to lower the temperature of the substrate 1 to 510° C. and the valve for the carrier gas comprising nitrogen was changed over to start feeding of nitrogen into the reaction furnace. Ten minutes after that, the valve of the pipe for TMG and the valve of the pipe for ammonia were changed over to feed TMG and ammonia into the reaction furnace, thereby forming a buffer layer 2 comprising GaN on the substrate. The buffer layer 2 was grown over about 10 minutes and thereafter, the valve of the pipe for TMG was changed over to stop feeding of TMG and to finish the growth of the buffer 2.

After the formation of buffer layer 2, the temperature of the substrate 1 was elevated to 1,060° C. During the elevation of temperature, an ammonia gas was flowed into the reaction furnace in addition to the nitrogen and hydrogen carrier gases to prevent the buffer layer 2 from sublimating. After confirming that the temperature was stabilized at 1,060° C., the valves of pipes for TMG and Cp2Mg were changed over to feed a gas containing these starting material gases into the reaction furnace, thereby growing a p-type layer 3 comprising an Mg-doped GaN on the buffer layer 2.

The p-type layer was grown over about 2 hours and thereafter, the valves of pipes for TMG and Cp₂Mg were changed over to stop feeding the starting materials into the reaction furnace and to finish the growth.

After the completion of growth of the p-type layer 3, the induction heating-type heater was controlled to lower the temperature of the substrate 1 to room temperature over 20 minutes. During the lowering of temperature, the atmosphere inside the reaction furnace was composed of ammonia, nitrogen and hydrogen similar to the atmosphere during the growth but after confirming that the temperature of the substrate 1 was lowered to 300° C., the feeding of ammonia and hydrogen was stopped. Thereafter, the substrate temperature was lowered to room temperature while flowing a nitrogen gas and then the sample was taken out into atmosphere.

Subsequently, an Ni thin film as a catalyst layer 7 was formed on the surface of the obtained sample by vapor deposition.

First, the sample was cleaned. After ultrasonic cleaning in acetone for 10 minutes, the sample was transferred into an ion-exchanged water and water-washed for 3 minutes while overflowing water. Thereafter, the sample was placed in hydrochloric acid poured into a beaker, left standing as it is for 10 minutes and then, again water-washed for 3 minutes in the beaker while overflowing water.

The sample of which surface was thus washed was fixed in a vacuum evaporator. The sample was placed on a fixture such that the sample surface faced downward and then, a small amount of Ni material was placed on a tungsten-made boat for resistance heating disposed under the fixture. Thereafter, the bell jar was closed and the inside was decompressed to 3×10⁻⁶ Torr using an oil rotary pump and an oil diffusion pump.

After confirming the degree of vacuum, a current was passed to the boat for resistance heating while observing the boat through a window for inspecting the inside of bell jar. After confirming that the Ni material was completely dissolved, the shutter intercepting the boat from the sample was opened. Thereafter, the current value was elevated while monitoring the film formation rate by a quartz plate-type film thickness meter and when the catalyst layer 7 comprising an Ni thin film reached a film thickness of 10 nm, the shutter was again closed.

After the completion of vapor deposition, the sample was left standing for about 15 minutes to allow the boat to cool, the bell jar was then released and the sample was taken out therefrom.

Through these steps, a sample 10 composed of a substrate 1, a buffer layer 2 having a film thickness of 20 nm, a p-type layer 3 comprising GaN doped with 1×10²⁰ cm⁻³ of Mg and having a film thickness of 2 μm, and a catalyst layer 7 comprising an Ni thin film, was fabricated.

Subsequently, the sample 10 was annealed as follows to manufacture a sample 11 having a p-type layer 3 capable of exerting electrical conductivity.

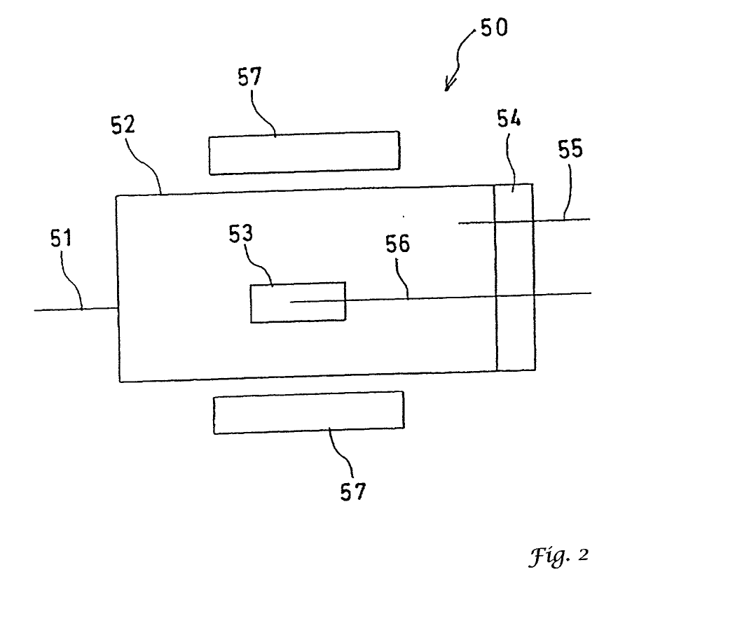

FIG. 2 is a plan view schematically showing an annealing furnace for use in the annealing of Sample 10. The annealing furnace 50 is an infrared gold furnace designed so that a carbon-made susceptor 53 can be disposed inside a quartz-made reactor tube 52 into which various gases can be flowed through a gas inlet 51. The annealing furnace 50 has a vacuum pump (not shown) connected through a vacuum flange 54 and a gas outlet 55, and the inside of the reactor tube 52 can be vacuumized. A thermocouple 56 for monitoring the temperature can be inserted into the inside of the carbon-made susceptor 53 and, based on a signal from the thermocouple 56, the power of the infrared heater 57 and the temperature of Sample 10 can be controlled.

Using the annealing furnace 50, Sample 10 was annealed as follows.

At first, the susceptor 53 was taken out, Sample 10 was placed thereon, susceptor 53 was inserted into the reaction tube 52, and the vacuum flange 54 was fixed. Thereafter, the inside of the reactor tube 52 was vaccumized by a vacuum pump and purged with a nitrogen gas as an atmosphere gas for the annealing. After repeating this operation 3 times, the inside of the reactor tube 52 was returned to an atmospheric pressure, and the atmosphere gas was flowed into the inside of the reactor tube 52 at a flow rate of 0.5 sccm for 5 minutes.

After the atmosphere gas was flowed for 5 minutes, the infrared heater 57 was turned on to elevate the temperature of Sample 10. While still flowing the atmosphere gas at the above-described flow rate, the temperature of Sample 10 was elevated to 300° C. over 8 minutes, the current of the infrared heater 57 was set to 0 to stop the heating of Sample 10 after the sample was kept at 300° C. for 10 minutes. At the same time, a nitrogen gas as the atmosphere gas was charged over to a cooling gas comprising only nitrogen and the cooling gas was flowed at a flow rate of 40 sccm (standard cc per minute). In this state, the temperature of the sample was lowered to room temperature over 15 minutes.

After confirming that the susceptor 53 was at room temperature, the inside of reactor tube 52 was vacuumized by a vacuum pump and purged with a nitrogen gas. Then the vacuum flange 54 was released, the susceptor 53 was taken out, and Sample 11 was recovered after annealing.

Thereafter, Sample 11 was impregnated with hydrochloric acid and adjusted to room temperature for 10 minutes to remove the catalyst layer 7 comprising Ni formed on the sample surface. As a result of this treatment, a Ni thin film formed on the surface was dissolved, and Sample 12 was obtained. The surface of the sample 12 lost the metal color and the colorless and transparent color inherent in GaN was restored.

Subsequently, the carrier concentration of the p-type layer 3 comprising an Mg-doped GaN of Sample 12 resulting from the annealing above was measured. The measurement of carrier concentration was performed as follows using the Hall effect measurement of the Van der Pauw method.

The sample cut into a 7-mm square was impregnated with acetone in a beaker under application of an ultrasonic wave, impregnated with hydrochloric acid for 10 minutes and then washed with running water for 3 minutes. Thereafter, a circular electrode comprising Ni and having a diameter of 0.5 mm and a film thickness of 3,000 Å was formed at four corners of the sample by vapor deposition using a metal mask. In order to form ohmic contact between each electrode and the sample, the sample was annealed at 450° C. for 10minutes in an argon atmosphere.

The Hall effect measurement was performed by passing a current of 10 μA to the sample in a magnetic field of 3,000 G. The contact properties of the electrode showed ohmic properties and this revealed that the measurement was exactly performed. As a result of this measurement, it was found that the Mgdoped GaN layer 3 showed p-type conduction and the carrier concentration was 9×10¹⁶ cm⁻³.

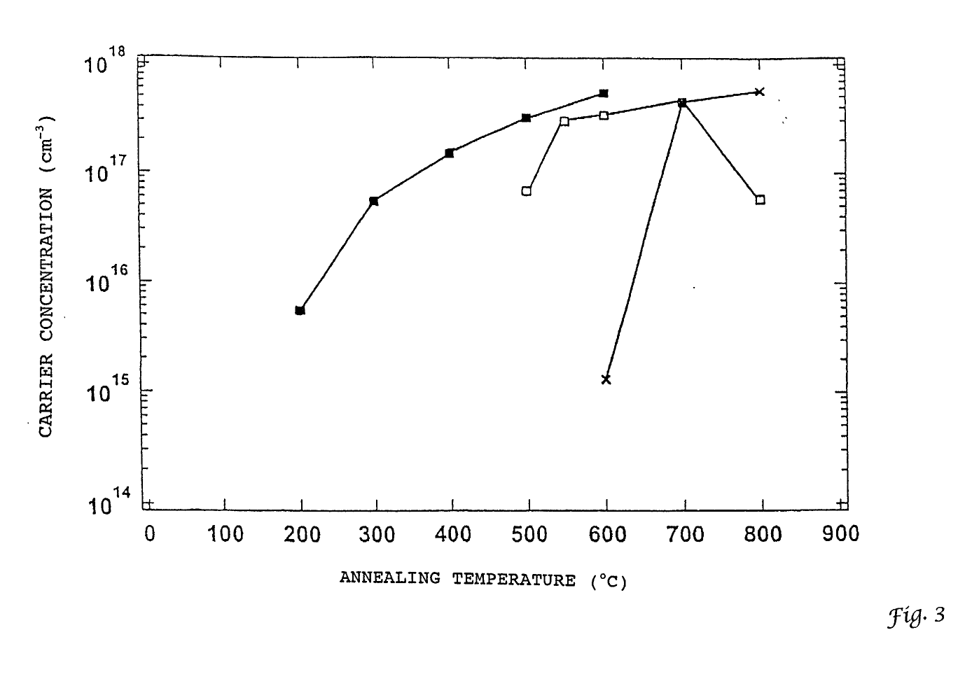

Sample 12 was produced by performing annealing at a temperature of 300° C. in a nitrogen gas atmosphere to allow the p-type layer 3 to exhibit electrical conductivity after the formation of catalyst layer 7. Here, in order to understand the relationship between the annealing temperature and the carrier concentration, samples were produced under the same conditions except for setting the annealing temperature not only at 300° C., but also at 200° C., 400° C., 500° C. or 600° C., and the carrier concentration of the p-type layer 3 of each sample was measured. FIG. 3 shows the measurement results, where the carrier concentrations are plotted by the mark ▪.

### COMPARATIVE EXAMPLE 1

In the same manner as in the first Example, a sample was produced by forming a GaN layer as a buffer layer on a sapphire substrate and stacking thereon an Mg-doped GaN layer. This sample was annealed using the same annealing furnace 50 as used in the first Example. The annealing was performed at 300° C. for 10 minutes in a nitrogen gas atmosphere in the same manner as in the first Example, except that a catalyst layer was not formed on the sample surface.

The thus annealed sample was measured with respect to the carrier concentration of the Mg-doped GaN layer in the same manner as in the first Example. The Mg-doped GaN layer (p-type layer) showed high resistance and therefore, the carrier concentration thereof could not be measured. This is considered because Mg in the p-type layer is inactivated by bonding to hydrogen.

Also, samples were produced under the same conditions except for elevating the annealing temperature to 600° C., 700° C. or 800° C., and the carrier concentration of the p-type layer of each sample was measured. FIG. 3 shows the measurement results, where the carrier concentrations are plotted by the mark x.

### EXAMPLE 1B

In the same manner as in the first Example, a sample was produced by forming a GaN layer as a buffer layer on a sapphire substrate, stacking thereon an Mg-doped GaN layer and further forming thereon a catalyst layer of Ni thin film. This sample was annealed using the same annealing furnace 50 as used in the first Example. The annealing of this sample was performed at 500° C. for 10 minutes in the same manner as in the first Example, except that a nitrogen gas containing 10% of oxygen was used as the atmosphere gas during the annealing.

The thus annealed sample was measured with respect to the carrier concentration of the Mg-doped GaN layer in the same manner as in the first Example. A catalyst layer of Ni thin film was formed and annealing was applied, and therefore, the Mg-doped GaN layer showed electrical conductivity and the carrier concentration was 1×10¹⁷ cm⁻³. The carrier concentration was almost equal to that in the first Example, however, when the outermost surface of the GaN layer (p-type layer) was observed by AES (Auger electron spectrometry), it was found that Ni oxide or Ga oxide was present on the surface of the GaN layer due to contamination generated upon annealing and the morphology and the contact property were damaged.

Also, samples were produced under the same conditions except for elevating the annealing temperature to 550° C., 600° C., 700° C. or 800° C., and the carrier concentration of the p-type layer of each sample was measured. FIG. 3 shows the measurement results, where the carrier concentrations are plotted by the mark ¤.

As seen from FIG. 3, in the samples (mark ▪) produced according to the method of the present invention, the p-type layer 3 exhibited a sufficiently high carrier concentration even by annealing at a temperature as low as 300° C. This is attributable to the fact that, as described above, an Ni thin film is used as a catalyst layer 7 and hydrogen is bonded to Ni in the catalyst layer 7, so that Mg in the p-type layer 3 is activated.

On the other hand, in Comparative Example 1 (mark x), a catalyst layer is not used, and therefore, the acceptor impurity (Mg in this case) remains bonded to hydrogen. As a result, a sufficiently high carrier concentration can be obtained only at a high temperature of 700° C. With a temperature in the region higher than that, the thermal decomposition of the gallium nitride-based compound semiconductor is accelerated to cause splitting off of the Group V element in the crystal. From the defects after the splitting off of Group V element, an electron is produced and therefore, a phenomenon that the carrier concentration decreases occurs as in the case of the carrier concentration at 800° C. Accordingly, annealing for a long period of time at a temperature of 700° C. or more is not preferred. The annealing is optimally performed at a temperature of 200 to 600° C. and in order to attain sufficiently high activity of the acceptor impurity, the annealing is preferably performed at a temperature of 300° C. or more.

In Example 1B (mark ¤), a catalyst of Ni thin film is used but since oxygen is contained in the atmosphere gas, despite a sufficiently high carrier concentration, Ni oxide or Ga oxide is present on the surface of the p-type layer due to generation of contamination. Therefore, the morphology and the contact property are damaged.

As such, according to the method of the present invention, since a desired carrier concentration can be obtained even by annealing at a low temperature, the crystal in the light-emitting layer is not damaged. In addition, since the annealing is performed in a nitrogen gas atmosphere contamination does not occur.

Furthermore, since the metal constituting the catalyst layer 7 is not necessary to be a noble metal, such as Pd, the cost can be reduced.

For removing the layer comprising a noble metal, such as Pd, a treatment with a strong acid at a high temperature or a treatment by irradiation of a high energy ray is necessary. As a result, the surface after the removal becomes coarse causes damages, however, since Ni or the like is used, the catalyst layer can be swiftly removed without causing any damage on the surface and accordingly, good ohmic contact can be realized with an electrode which is afterward formed on the surface.

In the first Example, the film thickness of the catalyst layer 7 formed on the p-type layer 3 is preferably on the order of 1 to 100 nm. For bonding hydrogen atoms diffusing from the crystal of p-type layer 3, the constituent material of the catalyst layer is sufficient if it is present in an amount of this range. If the catalyst layer 7 is excessively thick, the hydrogen atom cannot be eliminated from the catalyst layer into the vapor phase and a phenomenon of the hydrogen atoms again diffusing within the crystal may occur. The numerals of the film thickness set forth here are an optimal value found by the present inventors through an experiment by taking account of such a phenomenon.

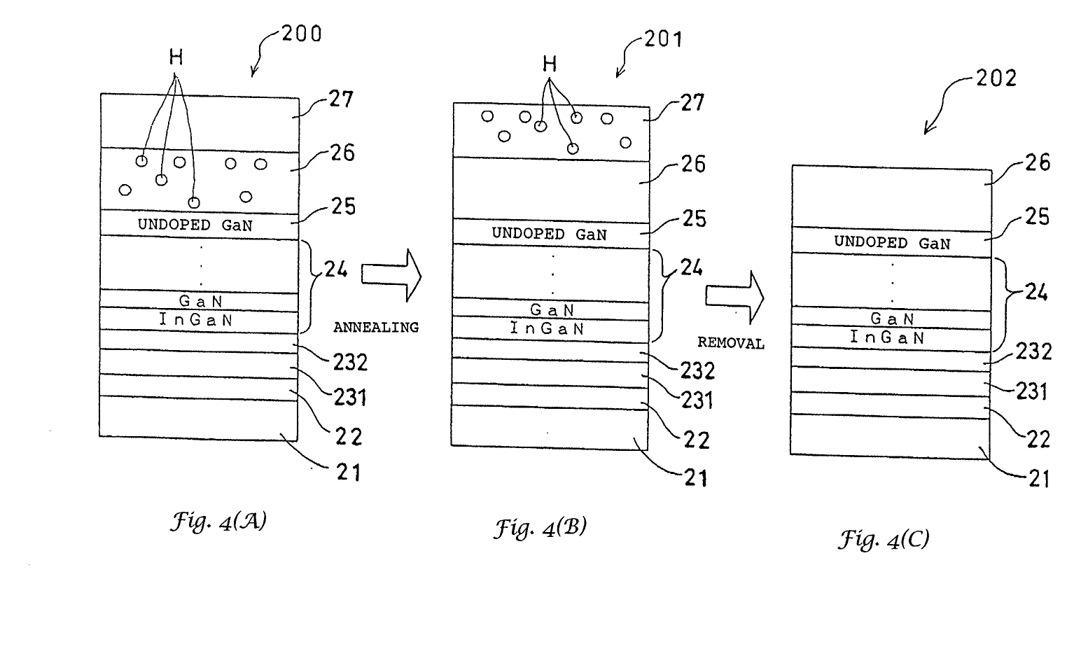

A second embodiment of the present invention is described below by referring to FIGS. 4(A)-(C) and Example 2.

### EXAMPLE 2

FIGS. 4(A)-(C) are view for explaining the method for producing a semiconductor light-emitting device (semiconductor light-emitting diode) constituted using the p-type gallium nitride-based compound semiconductor produced according to the method of the present invention.

A buffer layer 22 comprising AlN, an n-type layer 231 comprising an undoped GaN, an n-type layer 232 comprising an Si-doped AlGaN, multiquantum well (MQW) layer 24 comprising an InGaN layer and a GaN layer, an undoped GaN layer 25, and a p-type layer 26 comprising an Mg-doped AlGaN were stacked in sequence on a substrate 21 comprising sapphire using the MOCVD method to produce a wafer having a multilayer structure for a semiconductor light-emitting device.

On this wafer having a multilayer structure, a catalyst layer 27 comprising Co and having a film thickness of 1 nm was formed by a resistance heating method in the same manner as in the first Example using the same vapor deposition machine to produce Sample 200 (see, FIG. 4(A)). This sample was annealed at 400° C. for 5 minutes in a vacuum at a pressure of 3×10⁻³ Torr in the same manner as in the first Example using the same annealing furnace 50. As such, Sample 201 was produced (see, FIG. 4(B)). Thereafter, the catalyst layer 27 comprising Co was removed in the same manner as in the first Example to produce Sample (wafer) 202 having a p-type layer 26 as the outermost surface (see, FIG. 4(C)).

The carrier concentration of the p-type layer 26 as the outermost surface of the annealed wafer 202 was measured in the same manner as in the first Example and the carrier concentration was about 6×10¹⁶ cm⁻³ and a p-type conduction was exhibited. More specifically, similar to the first Example, hydrogen bonded with Mg in the p-type layer 26 migrated to the catalyst layer 27 by the annealing and bonded with Co in the catalyst 27. As a result, Mg in p-type layer 26, which had been inactivated by bonding with hydrogen, was activated and enabled to freely migrate and the carrier concentration in the p-type layer 26 was elevated.

On the wafer 202 after the completion of annealing, a bonding pad having a structure where titanium and gold were stacked, and a transparent electrode having a structure where gold and nickel oxide were stacked were formed in sequence from the surface side of the p-type electrode 26 by a known photolithography method to produce a p-side electrode.

Thereafter, the wafer 202 was dry-etched to expose the n-type layer 231 in a portion of forming an n-side electrode and on the exposed portion, an n-side electrode comprising titanium was produced.

The wafer on which p-side and n-side electrodes were formed above was subjected to a treatment of grinding and polishing the back surface of the substrate 21 to provide a mirror surface. Thereafter, the wafer was cut into 350-μm square chips and the square chip was placed on a lead frame so that the electrodes came upward, and bonded to a lead frame through a gold line to fabricate a semiconductor light-emitting diode.

A forward current was passed between the p-side electrode and the n-side electrode of the thus-fabricated light-emitting diode, and as a result, the forward voltage at a current of 20 mA was 3.6 V. The light emission was observed through the p-side transparent electrode, and the emission wavelength was 465 mm and the emission power output was 3 cd.

### EXAMPLE 2B

A wafer having a multilayer structure was produced by the MOCVD method in the same manner as in the second Example. In the same manner as in the second Example, a Co thin film was formed on the surface, then the wafer was annealed for 10 minutes in a nitrogen gas atmosphere containing oxygen to activate Mg in the AlGaN layer and at the same time, the Co thin film was removed to produce a p-type layer comprising AlGaN.

The carrier concentration of the p-type layer as the outermost surface of the annealed wafer was measured in the same manner as in the first Example and the conduction type was p-type and the carrier concentration was about 7×10¹⁷ cm⁻³.

On the wafer after the completion of annealing, a p-side electrode and an n-side electrode were produced in the same manner as in the second Example. Using this wafer, a light-emitting diode fabricated in the same manner as in the second Example.

A forward current was passed between the p-side electrode and the n-side electrode of the thus-fabricated light-emitting diode, and as a result, the forward voltage at a current of 20 mA was 5.2 V. The light emission was observed through the p-side transparent electrode, and the emission wavelength and the emission power output were almost the same as those in the second Example.

As such, there was no difference in the emission power output of the light-emitting diode between the second Example and Example 2B, but a great different was present in the forward voltage at a current of 20 mA. This is considered to have occurred because in Example 2B, the annealing was performed in a nitrogen gas atmosphere containing oxygen and therefore, Co oxide or Ga oxide as contamination was generated on the outermost surface of the p-type layer to change the morphology and the contact property for the worse, and the contact resistance of the p-side electrode was elevated.

### EXAMPLE 2C

A wafer was fabricated almost in the same manner as in the second Example except that in the second Example, a Co-layer was formed on a p-type layer 26 comprising an Mg-doped AlGaN, whereas in Example 2C, Pd was used in place of Co and the Pd layer was removed using the boiling in aqua regia. The carrier concentration of the p-type layer comprising AlGaN as the outermost layer of this wafer was about 6×10¹⁷ cm⁻³.

On this wafer, a p-side electrode and an n-side electrode were produced in the same manner as in the second Example to fabricate a light-emitting diode.

A forward current was passed between the p-side electrode and the n-side electrode of the thus-fabricated light-emitting diode, and as a result, the forward voltage at a current of 20 mA was 6.0 V. The light emission was observed through the p-side transparent electrode, and the emission wavelength and the emission power output were almost the same as those in the second Example.

Similar to Example 2B, there was no difference in the emission power output of the light-emitting diode between the second Example and Example 2C, but a great different was present in the forward voltage at a current of 20 mA. This is considered to occur because in Example 2C, the Pd layer was removed by the boiling in aqua regia, and therefore, the outermost layer of the p-type layer became coarse and damaged.

In the description above, the gallium nitride-based compound semiconductor is a Group Ill-V compound semiconductor based on GaN, where a part of Ga is displaced by a Group III element, such as B, In or Al, and a part of N is displaced by a Group V element, such as As or P. One example is a seven-component gallium nitride-based compound semiconductor represented by formula: (AlₓB_{y}In_{z}Ga_{1-x-y-z})N₁₋ᵢ₋ⱼPᵢAsⱼ (wherein 0≦x≦1, 0≦y≦1, 0≦z≦1, 0≦i≦1, 0≦i≦1).

In the first Example, the annealing was performed in a nitrogen gas atmosphere but the annealing may be performed in another inert gas, for example, in a rare gas such as Ar. Also, in the second Example, the annealing was performed in a vacuum of 3×10^{—3} Torr but the pressure may be sufficient if it is a pressure on the order of not allowing oxidation to proceed and the pressure value is not particularly limited.

Furthermore, the catalyst layer was formed using Ni or Co, but the present invention is not limited thereto, and the metal which can be used as a catalyst layer may be sufficient if it is a metal having a smaller heat of formation for a metal hydride compound than that of the p-type impurity. Examples thereof include Fe, Mn, Cr, V, Ti, Re, W, Ta, Hf, Lu, Gd, Ce, La, Ru, Mo, Zr, Y, Au, Ag, Cu, Al and Bi. These metals are known to have a bonding energy with hydrogen larger than that of a p-type impurity such as Mg. By utilizing a catalyst layer comprising a material having such properties, the hydrogen atom of which bonding with the p-type impurity is cut during annealing migrates in the crystal, contacts with the catalyst layer formed on the surface and more preferentially bonds with a metal constituting the catalyst layer. Accordingly, the hydrogen in the crystal can be more effectively removed.

The catalyst layer was a monolayer film comprising one metal but the catalyst layer may also be structured as a multilayer film comprising one metal or an alloy of two or more metals or a compound.

As described in the foregoing, according to the present invention, a catalyst layer comprising a metal having a smaller heat of formation for the metal hydride compound than that of the p-type impurity is formed on a gallium nitride-based compound semiconductor layer doped with a p-type impurity and the catalyst layer is annealed so that hydrogen bonded with the p-type impurity bonds with a metal in the catalyst layer. Therefore, the p-type impurity inactivated by hydrogen is activated and freely migrates to elevate the carrier concentration. As a result, the gallium nitride-based compound semiconductor layer doped with the p-type impurity can fully exert the p-type function.

A desired carrier concentration can be obtained even by annealing at a low temperature, and therefore, deterioration does not occur in the crystal of the light-emitting layer. Furthermore, contamination is not generated. Accordingly, when a light-emitting device is fabricated, good contact properties can be kept between the p-type gallium nitride-based compound semiconductor layer and the electrode, and in turn the properties as a light-emitting device can be improved.

In addition, it is not necessary to use a noble metal, such as Pd, as the metal constituting the catalyst layer, and therefore, the cost can be reduced.

For removing the layer comprising a noble metal such as Pd, a treatment with a strong acid at a high temperature or a treatment by irradiation of a high energy ray is necessary. As a result, the surface after the removal becomes coarse and causes damages. However, since Ni or the like is used, the catalyst layer can be swiftly removed without causing any damage on the surface, and accordingly, good ohmic contact can be realized with an electrode, which is afterward formed on the surface. As a result, the properties of the light-emitting device can be improved.

The film thickness of the catalyst layer is from 1 to 100 nm so that hydrogen atoms diffusing from the crystal in the gallium nitride-based compound semiconductor layer doped with a p-type impurity can be satisfactorily captured and at the same time, a phenomenon that the hydrogen atom does not split off from the catalyst layer into the vapor phase but diffuses again within the crystal, which occurs in the case of a catalyst layer having an excessively large thick, can be prevented. As a result, the gallium nitride-based compound semiconductor layer doped with a p-type impurity can be converted into a p-type layer without fail.

While the invention has been described in detail and with reference to specific Examples thereof, it will be apparent to one skilled in the art that various changes and modifications can be made therein without departing from the spirit and scope thereof.

What is claimed is:

1. A method for producing a p-type gallium nitride-based compound semiconductor comprising:
producing a gallium nitride-based compound semiconductor layer doped with a p-type impurity;
producing a catalyst layer comprising a metal, alloy or compound on said gallium nitride-based compound semiconductor layer; and
annealing the gallium nitride-based compound semiconductor layer fixed with said catalyst layer.

2. The method for producing a p-type gallium nitride-based compound semiconductor as claimed in claim 1, wherein said catalyst layer comprises a metal, alloy or compound having a smaller heat of formation for a metal hydride compound than that of the p-type impurity.

3. The method for producing a p-type gallium nitride-based compound semiconductor as claimed in claim 2, wherein said catalyst layer is a monolayer or multilayer film comprising a metal, alloy or compound containing at least one element selected from the group consisting of Ni, Co, Fe, Mn, Cr, V, Ti, Re, W, Ta, Hf, Lu, Gd, Ce, La, Ru, Mo, Zr, Y, Au, Ag, Cu, Al and Bi.

4. The method for producing a p-type gallium nitride-based compound semiconductor as claimed in claim 2, wherein said catalyst layer is a monolayer or multilayer film comprising a metal, alloy or compound containing Ni.

5. The method for producing a p-type gallium nitride-based compound semiconductor as claimed in any one of claims 1 to 4, wherein said annealing is performed at a temperature of 200° C. or more.

6. The method for producing a p-type gallium nitride-based compound semiconductor as claimed in any one of claims 1 to 4, which further comprises stripping the catalyst layer after said annealing.

7. The method for producing a p-type gallium nitride-based compound semiconductor as claimed in any one of claims 1 to 4, wherein said catalyst layer has a film thickness of 1 to 100 nm.

8. A method for producing a gallium nitride-based compound semiconductor light-emitting device comprising providing an n-type layer and a light-emitting layer each comprising a gallium nitride-based compound semiconductor, and providing a p-type layer comprising a gallium nitride-based compound semiconductor through the following steps:
producing a gallium nitride-based compound semiconductor layer doped with a p-type impurity;
producing a catalyst layer comprising a metal, alloy or compound on said gallium nitride-based compound semiconductor layer;
annealing the gallium nitride-based compound semiconductor layer fixed with said catalyst layer; and
stripping said catalyst layer.

9. The method for producing a gallium nitride-based compound semiconductor light-emitting device as claimed in claim 8, wherein said catalyst layer comprises a metal, alloy or compound having a smaller heat of formation for a metal hydride compound than that of the p-type impurity.

10. The method for producing a gallium nitride-based compound semiconductor light-emitting device as claimed in claim 9, wherein said catalyst layer is a monolayer or multilayer film comprising a metal, alloy or compound containing at least one element selected from the group consisting of Ni, Co, Fe, Mn, Cr, V, Ti, Re, W, Ta, Hf, Lu, Gd, Ce, La, Ru, Mo, Zr, Y, Au, Ag, Cu, Al and Bi.

11. The method for producing a gallium nitride-based compound semiconductor light-emitting device as claimed in claim 9, wherein said catalyst layer is a monolayer or multilayer film comprising a metal, alloy or compound containing Ni.

12. The method for producing a gallium nitride-based compound semiconductor light-emitting device as claimed in any one of claims 8 to 11, wherein said annealing is performed at a temperature of 200° C. or more.

13. The method for producing a gallium nitride-based compound semiconductor light-emitting device as claimed in any one of claims 8 to 11, wherein said catalyst layer has a film thickness of 1 to 100 nm.

14. A gallium nitride-based compound semiconductor light-emitting device comprising an n-type layer, a light-emitting layer and a p-type layer each comprising a gallium nitride-based compound semiconductor, wherein said p-type layer is formed by providing a catalyst layer comprising a metal, alloy or compound on a gallium nitride-based compound semiconductor layer doped with a p-type impurity, annealing the gallium nitride-based compound semiconductor layer fixed with said catalyst layer, and stripping the catalyst layer, wherein the p-type impurity in the p-type layer is activated.
